(19) United States
(12) Patent Application Publication
(10) Pub. No.: US 2014/0003022 A1
(43) Pub. Date: Jan. 2, 2014

(54) FLAT PANEL DISPLAY DEVICE

(71) Applicant: Byung-Jun LEE, Yongin-City (KR)

(72) Inventor: Byung-Jun LEE, Yongin-City (KR)

(21) Appl. No.: 13/676,459

(22) Filed: Nov. 14, 2012

(30) Foreign Application Priority Data
Jun. 29, 2012 (KR) 10-2012-0070850

(51) Int. Cl. H05K 7/02

(52) U.S. Cl. CPC H05K 7/02
USPC 361/809

(57) ABSTRACT

A flat panel display device includes a film substrate having a pixel region and a non-pixel region defined therein, at least two pad parts formed at the non-pixel region, and at least one hole formed between the pad parts adjacent to each other, wherein the pixel region has a plurality of pixels arranged therein and a non-pixel region is disposed around the pixel region.

### CROSS-REFERENCE TO RELATED APPLICATION

This application claims priority under 35 U.S.C. §119 to Korean Patent Application No. 10-2012-0070850, filed on Jun. 29, 2012, in the Korean Intellectual Property Office, the entire contents of which is incorporated herein by reference.

### BACKGROUND

1. Field

Embodiments relate to a flat panel display device, and more particularly, to a flat panel display device using a flexible film substrate.

2. Description of the Related Art

A flat panel display device such as an organic light emitting diode (OLED) and a liquid crystal display (LCD) is generally formed on a transparent substrate made of glass or quartz. The glass or the quartz may have a heavy weight and may be easily damaged if small impact is applied thereto.

Therefore, a technology of using a film substrate that is light, can withstand impacts, and is capable of being bent has been recently developed.

### SUMMARY

Embodiments are directed to a flat panel display device including a film substrate having a pixel region and a non-pixel region defined therein, at least two pad parts at the non-pixel region, and at least one hole between adjacent pad parts, wherein the pixel region has a plurality of pixels arranged therein and the non-pixel region is arranged around the pixel region.

The film substrate may be made of a plastic-based material.

The plastic-based material may be selected from a group of polyester, polyvinyl, polycarbonate, polyethylene, polyacetate, polyimide, polyethersulfone (PES), polyacrylate (PAR), polyethylenenaphthalate (PEN), polyethyleneterephthalate (PET), and the like.

One side of the hole may be open to the outermost perimeter of the film substrate.

The at least one hole may include a plurality of the holes arranged in a direction perpendicular to a direction in which the pad parts are arranged.

Each pad of the pad parts may be electrically connected to the pixels through a plurality of wirings.

The flat panel display device may further include an anisotropic conductive film on the pad parts. A printed circuit board may be on the anisotropic conductive film and electrically connected to the pad parts through the anisotropic conductive film.

The printed circuit board may be electrically connected to the pad parts by thermo-compression.

The printed circuit board may be mounted with a driving integrated circuit receiving data and control signals from an outside and providing driving signals to the pixels of the film substrate.

### BRIEF DESCRIPTION OF THE DRAWINGS

Features will become apparent to those of ordinary skill in the art by describing in detail exemplary embodiments with reference to the attached drawings in which:

FIG. 1 and FIG. 2 are plan views describing a flat panel display device according to an exemplary embodiment.

FIG. 3 is a cross-sectional view describing the flat panel display device according to the exemplary embodiment.

FIG. 4 and FIG. 5 are plan views of a film substrate according to another exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

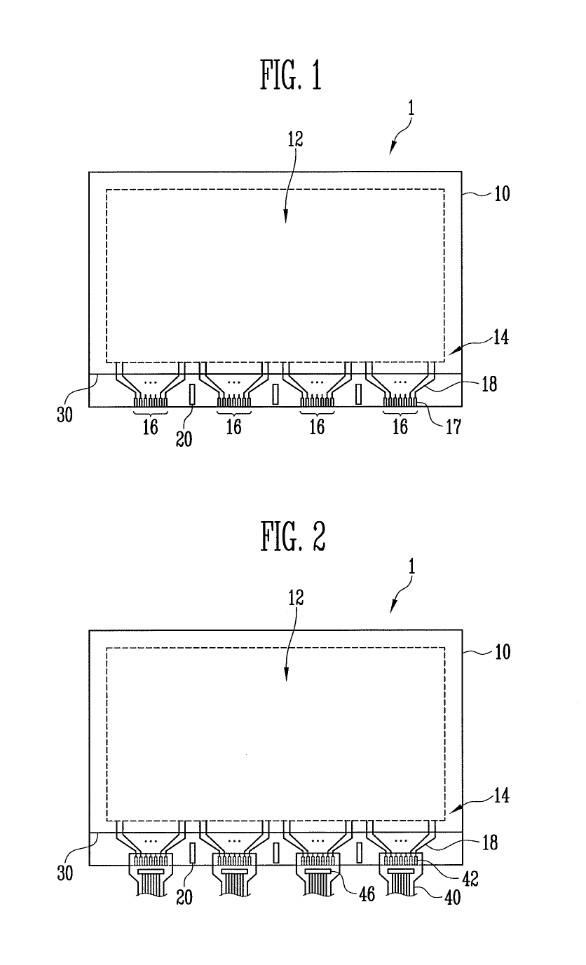

FIG. 1 and FIG. 2 are schematic plan views describing a flat panel display device according to an exemplary embodiment.

Referring to FIG. 1, the flat panel display device 1 includes a film substrate 10 in which a pixel region 12 having a plurality of pixels arranged therein and a non-pixel region 14 disposed around the pixel region 12 are defined; and a sealing unit 30 disposed to face the film substrate 10 in order to seal the pixel region 12. The film substrate 10 and the sealing unit 30 are adhered to each other by a sealing material (not shown) applied along an edge of the non-pixel region 14.

The film substrate 10 has a plurality of pixels arranged in a column direction and a row direction in the pixel region 12 thereof. The plurality of pixels may be connected to each other in a matrix structure between a plurality of scanning lines arranged in the column direction and a plurality of data lines arranged in the row direction. Each pixel may include a pixel circuit for driving the pixel. The pixel circuit may include a thin film transistor driving the pixel and a capacitor connected to the thin film transistor to maintain a signal.

The plurality of pixels may be configured as a liquid crystal cell or an organic light emitting diode (OLED).

The liquid crystal cell includes a pixel electrode, a common electrode, and a liquid crystal arranged between the pixel and common electrodes.

The organic light emitting diode (OLED) includes an anode electrode, a cathode electrode, and an organic thin film layer formed between the anode and cathode electrodes. The organic thin film layer may have a structure in which a hole transport layer, an organic lighting emitting layer, and an electron transport layer are stacked and may further include a hole injecting layer and an electron injecting layer.

The non-pixel region 14 of the film substrate 10 is provided with a pad part 16 for receiving a signal from the outside. The pad part 16 may be configured as a plurality of pads 17. In addition, at least two pad parts 16 may be disposed at an edge of the film substrate 1 at a predetermined interval. The pads 17 of each pad part 16 are electrically connected to the pixels of the pixel region 12 through wirings 18, respectively. The wirings 18 may include a scan line, a data line, and power voltage line that are extended from the pixel region 12 to the non-pixel region 14. The pad 17 and the wiring 18 may be formed of a metal layer such as gold, silver, aluminum, copper, or the like, or a transparent oxide conductive layer such as ITO and IZO.

At least one hole 20 is formed between the pad parts 16 formed in the film substrate 10. The hole 20 may have a form in which it penetrates through the film substrate 10 and may have a length longer than that of the pads 17.

The film substrate 10 is made of a plastic-based material, for example, a material selected from a group of polyester, polyvinyl, polycarbonate, polyethylene, polyacetate, polyimide, polyethersulfone (PES), polyacrylate (PAR), polyethylenenaphthalate (PEN), polyethyleneterephthalate (PET), and the like. The film substrate 10 may have a flexible thin film form.

The sealing unit 30 may be formed in a thin film form using the same material as the material of the film substrate 10 or may be formed as a structure in which a glass substrate, an organic film, and an inorganic film are stacked. The sealing unit may have a cap shape.

Although FIG. 1 shows a case in which the plurality of pad parts 16 are arranged only at one side of the film substrate 10, the pad parts 16 may be additionally formed at another side of the film substrate 10 as desired. For example, the plurality of pad parts connected to the plurality of scanning lines arranged in the column direction may be formed at one side of the film substrate 10 and the plurality of pad parts connected to the plurality of data lines arranged in the row direction may be formed at another side thereof.

Referring to FIG. 2, the flat panel display device 1 according to the exemplary embodiment includes a plurality of printed circuit boards 40, each being electrically connected to one of the plurality of pad parts 16.

The printed circuit board 40 may be mounted with a driving integrated circuit 46 receiving data and control signals from the outside and providing the driving signals to the pixels of the film substrate 10. The printed circuit board 40 may be a flexible printed circuit board (FPCB). The driving integrated circuit 46 may be a scan driving unit or a data driving unit and may include a controller, a power supply voltage supplying unit, and the like.

The pad part 42 connected to an output terminal of the driving integrated circuit 46 is electrically connected to the pad part 16 of the film substrate 10.

When data and control signals and the power voltage are provided from the outside to the printed circuit board 40, scan and data signals generated by the driving integrated circuit 46 may be provided to each pixel through the pad part 16 of the film substrate 10, such that a predetermined image is displayed through the pixel region 12.

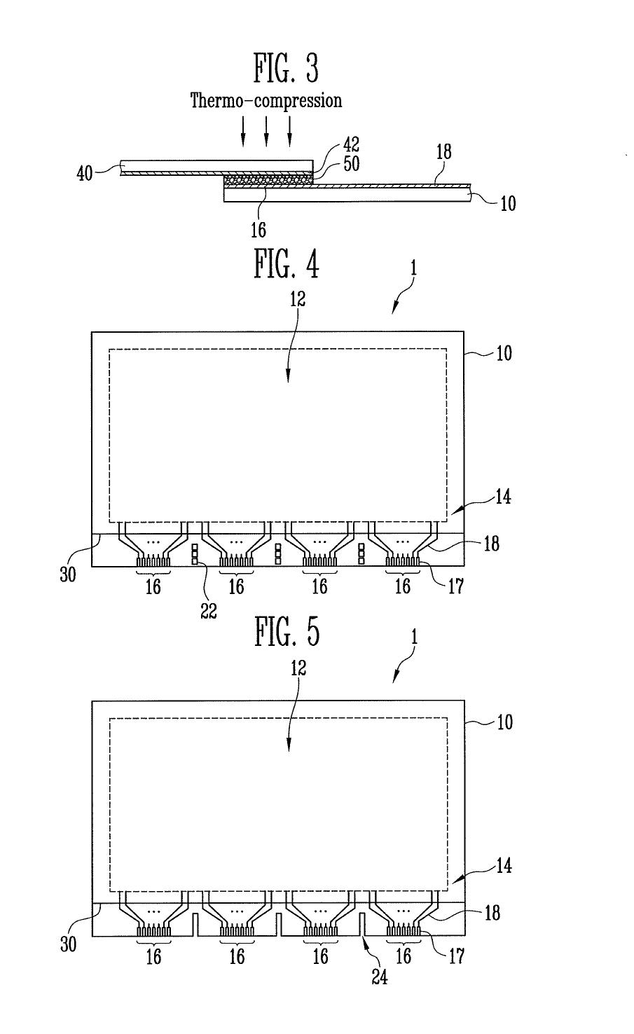

FIG. 3 is a cross-sectional view showing a state in which the pad part 42 of the printed circuit board 40 is connected to the pad part 16 of the film substrate 10.

An anisotropic conductive film 50 is arranged on the pad part 16 of the film substrate 10 and the printed circuit board 40 is arranged so that the pad part 42 of the printed circuit board 40 is disposed on the anisotropic conductive film 50. In this state, for example, when the printed circuit board 40 is pressed using a heated bar shaped compressing unit (not shown), conductive balls of the anisotropic conductive film 50 are broken, such that the pad part 42 of the printed circuit board 40 is electrically connected to the pad part 16 of the film substrate 10 through the broken conductive balls.

In order to electrically connect the printed circuit board 40 to each of the plurality of pad parts 16, the thermo-compression process as described above is repeatedly performed. When the printed circuit board 40 is thermo-compressed to one pad part 16 and the printed circuit board 40 is then thermo-compressed to another pad part 16 adjacent to one pad part 16, heat may be transferred from the heated compressing unit to the film substrate 10 through the printed circuit board 40. The heat transferred to the film substrate 10 may be transferred toward the other pad part 16 adjacent to the pad part 16 that has already been thermo-compressed. In this case, when the heat is transferred to the anisotropic conductive film 50 between the already thermo-compressed pad part 16 and the pad part 42, air bubbles, and the like, may occur, such that the compression quality may be deteriorated and the pad 17 or the wiring 18 may be peeled off due to thermal deformation of the film substrate 10.

However, according to the exemplary embodiment, lateral diffusion of the heat may be blocked by the hole 20 formed between the pad parts 16 in the film substrate 10. Accordingly, it may be possible to excellently maintain the compression quality of the printed circuit board 40 to the pad part 16 of the film substrate 10 and to minimize the thermal deformation of the film substrate 10.

In order to minimize the thermal diffusion, an interval between the pad parts (16) may be increased. However, there is a limit to how much the interval may be increased within a limited area, such that it may be difficult to miniaturize the display device. On the other hand, according to the exemplary embodiment, it may possible to easily prevent the lateral diffusion of the heat without changing a design.

FIGS. 4 and 5 are plan views describing another exemplary embodiment. Although FIG. 1 shows a structure in which one hole 20 is formed between the pad parts 16, in another embodiments, a plurality of holes 22 may be arranged in a direction perpendicular to a direction in which the pad parts 16 are arranged between the pad parts 16, as shown in FIG. 4, or a hole 24 may be formed in which one side is open to the outmost surface or perimeter of the film substrate 10, as shown in FIG. 5.

In the structure shown in FIG. 4, a contact area between the film substrate and air is increased by the plurality of holes 22, thereby making it possible to promote diffusion of the heat to the outside. In the structure shown in FIG. 5, one side of the hole 24 is opened, thereby making it possible to more effectively block the diffusion of the heat.

By way of summation and review, the flat panel display device displays an image by a data and a control signal provided from the outside. To this end, a driving integrated circuit (IC), which is a driving device, is mounted on a substrate of the flat panel display device or a flexible printed circuit board, which is a printed circuit board having a driving device mounted thereon, is electrically connected to the flat panel display device.

The flexible printed circuit board (FPCB) may be electrically connected to the film substrate of the flat panel display device by a method such as a thermo-compression method, or the like. However, in this case, the film substrate may expand and the thin film formed on the film substrate may be damaged, due to high heat in a thermo-compression process. For example, a film substrate made of a plastic based material has a transition temperature lower than that of a glass substrate and an expansion coefficient higher than that of the glass substrate. Accordingly, a thin film formed on the substrate may be damaged due to a local difference of the expansion coefficient. Therefore, in order to solve these problems, a process for lowering a process temperature and improving stability may be used.

The film substrate according to embodiments has holes formed between the pad parts. The lateral diffusion of the heat may be prevented by the hole in a process of thermo-compressing the printed circuit board to the pad part of the film substrate. Accordingly, the compression quality of the printed circuit board to the pad part of the file substrate may be maintained and the thermal deformation of the film substrate may be minimized.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A flat panel display device, comprising:
a film substrate having a pixel region and a non-pixel region defined therein, at least two pad parts at the non-pixel region, and at least one hole between adjacent pad parts, wherein the pixel region has a plurality of pixels arranged therein and the non-pixel region is arranged around the pixel region.

2. The flat panel display device according to claim 1, wherein the film substrate is made of a plastic-based material.

3. The flat panel display device according to claim 2, wherein the plastic-based material is selected from a group of polyester, polyvinyl, polycarbonate, polyethylene, polyacetate, polyimide, polyethersulfone (PES), polyacrylate (PAR), polyethylenenaphthalate (PEN), polyethyleneterephthalate (PET), and the like.

4. The flat panel display device according to claim 1, wherein one side of the hole is open to the outermost perimeter of the film substrate.

5. The flat panel display device according to claim 1, wherein the at least one hole includes a plurality of holes arranged in a direction perpendicular to a direction in which the pad parts are arranged.

6. The flat panel display device according to claim 1, wherein each pad of the pad parts is electrically connected to the pixels through a plurality of wirings.

7. The flat panel display device according to claim 1, further comprising:
an anisotropic conductive film on the pad parts; and
a printed circuit board on the anisotropic conductive film and electrically connected to the pad parts through the anisotropic conductive film.

8. The flat panel display device according to claim 7, wherein the printed circuit board is electrically connected to the pad parts by thermo-compression.

9. The flat panel display device according to claim 7, wherein the printed circuit board is mounted with a driving integrated circuit receiving data and control signals from an outside and providing driving signals to the pixels of the film substrate.
